(19) United States
(12) Patent Application Publication
(10) Pub. No.: US 2021/0159882 A1
(43) Pub. Date: May 27, 2021

(54) SURFACE ACOUSTIC WAVE WAFER-LEVEL PACKAGE

(71) Applicant: WISOL CO., LTD., Gyeonggi-do (KR)

(72) Inventors: Chang Yup LEE, Gyeonggi-do (KR); Suk Hwan JANG, Gyeonggi-do (KR); Jin Ho HA, Gyeonggi-do (KR); Byung Hak KIM, Gyeonggi-do (KR)

(73) Assignee: WISOL CO., LTD.

(21) Appl. No.: 16/951,238

(22) Filed: Nov. 18, 2020

(30) Foreign Application Priority Data
Nov. 27, 2019 (KR) 10-2019-0154758

(51) Int. Cl. H03H 9/05; H03H 9/02; H03H 9/10; H03H 9/145

(52) U.S. Cl. CPC H03H 9/059; H03H 9/02543; H03H 9/0561; H03H 9/145; H03H 9/1092

(57) ABSTRACT

A surface acoustic wave wafer-level package includes a substrate, an interdigital transducer (IDT) electrode formed on the substrate, a connection electrode electrically connected to the IDT electrode, a side wall formed on the substrate and outside the IDT electrode, a cover formed above the side wall and the IDT electrode to form a cavity, together with the side wall, on the IDT electrode, a connection terminal electrically connected to the connection electrode and protruding above the cover, a first reinforcement layer formed on the cover to at least partially overlap the cavity in a vertical direction, a second reinforcement layer formed to cover the cover and the first reinforcement layer and having holes formed in a portion corresponding to the connection terminal and a portion corresponding to the first reinforcement layer, and bumps formed in the respective holes of the second reinforcement layer to protrude above the second reinforcement layer.

### CROSS-REFERENCE TO RELATED APPLICATION

This application claims the benefit under 35 USC § 119(a) of Korean Patent Application No. 10-2019-0154758, filed on Nov. 27, 2019, in the Korean Intellectual Property Office, the entire disclosure of which is incorporated herein by reference for all purposes.

### FIELD

The present invention relates to a surface acoustic wave device, and more particularly, to a surface acoustic wave wafer-level package.

### BACKGROUND

A surface acoustic wave (SAW) is an acoustic wave propagating along the surface of an elastic substrate, wherein the acoustic wave is generated from an electric signal as a result of a piezoelectric effect and the electric field of the acoustic wave is concentrated on the peripheries of the surface of the substrate and thus can interact with conduction electrons of a semiconductor element, which is immediately placed on the surface. A medium, through which the acoustic wave propagates, is a piezoelectric material, of which an electromechanical coupling coefficient is high and an acoustic wave energy loss is low. A semiconductor material has high electron mobility, an optimum resistivity and a low DC power element and thus can secure an optimum efficiency. A SAW device is to substitute an electric circuit to an electromechanical element by using the interactions between the SAW and the conduction electrons.

Since the wave energy of the SAW is concentrated and propagates on a solid surface, signal control is easy and the size of a device can be reduced. In addition, with the advent of high-quality piezoelectric materials, such as LiNbO3, LiTaO3, crystal, and PZT, it is possible to easily and efficiently generate, detect and control surface acoustic waves by forming a metal electrode (IDT: interdigital transducer) on the piezoelectric material surface. As a result, various high-function electronic devices that process high-frequency signals in the microwave range into surface acoustic waves are being developed and researched at an accelerated pace.

A surface acoustic wave SAW device includes an input electrode and an output electrode, which are made of a metal thin film in the shape of a comb and provided at both sides on the surface of the piezoelectric medium, wherein a high frequency is input and converted into a surface acoustic wave so as to detect propagation properties with the output electrode and recover the surface acoustic wave into an electric signal. There are delay lines, amplifiers, waveform converters, optical beam deflection elements, optical switches and the like as the application examples thereof.

In the manufacture of such a surface acoustic wave device and a semiconductor device, a manufacturing method using wafer-level package (WLP) technology is widely used in which the package process and testing are performed at a time at wafer level and then a chip is simply cut from the wafer to produce a finished product, in contrast to the more conventional method of slicing the processed wafer into individual chips and packaging the chips.

The wafer-level packaging enables the manufacture of a package as a complete product at wafer level, i.e., in a state where individual chips are not separated from a wafer. In addition, existing wafer manufacturing facilities and processes can be used as they are in manufacturing facilities or manufacturing processes used to manufacture packages. Since this WLP process allows a packaging process to be performed in a wafer state, compared to the conventional method of packaging on a chip-by-chip basis, hundreds to thousands of packages can be produced in a single packaging process, thereby significantly reducing manufacturing cost and investment cost.

FIG. 1 is a view showing a cross-sectional structure of a conventional surface acoustic wave (SAW) wafer-level package. As illustrated, the surface acoustic wave wafer-level package includes a substrate 10, an IDT electrode 20, a connection electrode 30, a side wall 40, a cover 50, and a connection terminal 60. Since the surface acoustic wave wafer-level package operates as a filter by arranging the IDT electrode 20 in a cavity 45 formed by the substrate 10, the sidewall 40, and the cover 50 and using mechanical vibration of the IDT electrode 20, the cavity 45 should be perfectly protected. However, the process of manufacturing an electronic device including a surface acoustic wave wafer-level package has a problem of being incapable of sufficiently enduring the high pressure of particularly a transfer molding process.

FIG. 2 shows the cavity 45 formed by the substrate 10, the side wall 40, and the cover 50 in a normal state, and FIG. 3 shows the cavity 45 after pressure P is applied by transfer molding. Referring to FIG. 3, as the cover 50 cannot withstand pressure P and droops down, the cavity 45 cannot be properly secured and the cover 50 touches the IDT electrode, resulting in a defect of failure of the device.

### SUMMARY

Therefore, the present invention has been made in view of the above problems, and an objective of the present invention is to provide a surface acoustic wave wafer-level package with improved pressure resistance that can withstand the pressure of transfer molding.

In one general aspect, there is provided a surface acoustic wave (SAW) wafer-level package including: a substrate; an interdigital transducer (IDT) electrode formed on the substrate; connection electrode formed on the substrate and electrically connected to the IDT electrode; a side wall formed on the substrate and outside the IDT electrode; a cover formed above the side wall and the IDT electrode to form a cavity, together with the side wall, on the IDT electrode; a connection terminal electrically connected to the connection electrode and protruding above the cover; a first reinforcement layer made of a metal material and formed on the cover to at least partially overlap the cavity in a vertical direction; a second reinforcement layer formed to cover the cover and the first reinforcement layer and having holes formed in a portion corresponding to the connection terminal and a portion corresponding to the first reinforcement layer; and bumps formed in the respective holes of the second reinforcement layer to protrude above the second reinforcement layer.

The first reinforcement layer may include Ti, Cu, Sn, Ni, or Au.

The second reinforcement layer may include an epoxy or a photoresist.

The bumps may include a solder paste, a solder ball, a copper plate, or a copper pillar.

The first reinforcement layer may be formed to completely overlap the cavity in the vertical direction.

The first reinforcement layer may be formed to partially overlap the cavity in the vertical direction.

A distance between adjacent bumps among the bumps may be 200 μm or less.

The second reinforcement layer may have a height of 10 μm or more from an upper surface of the first reinforcement layer.

Other features and aspects will be apparent from the following detailed description, the drawings, and the claims.

### BRIEF DESCRIPTION OF THE DRAWINGS

FIG. 1 is a view showing a cross-sectional structure of a conventional surface acoustic wave (SAW) wafer-level package.

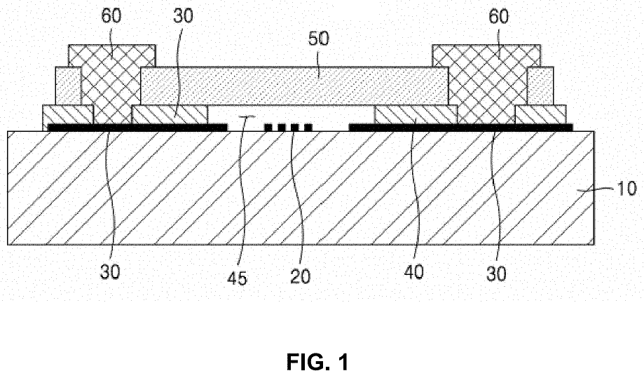

FIG. 2 shows a cavity formed by a substrate, a side wall, and a cover in a normal state.

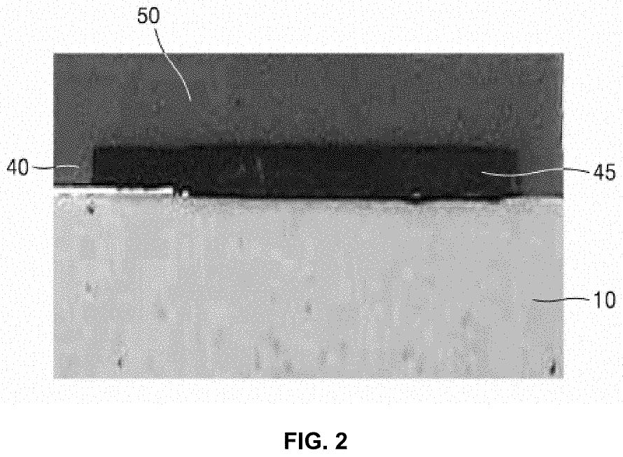

FIG. 3 shows a cavity after pressure is applied by transfer molding.

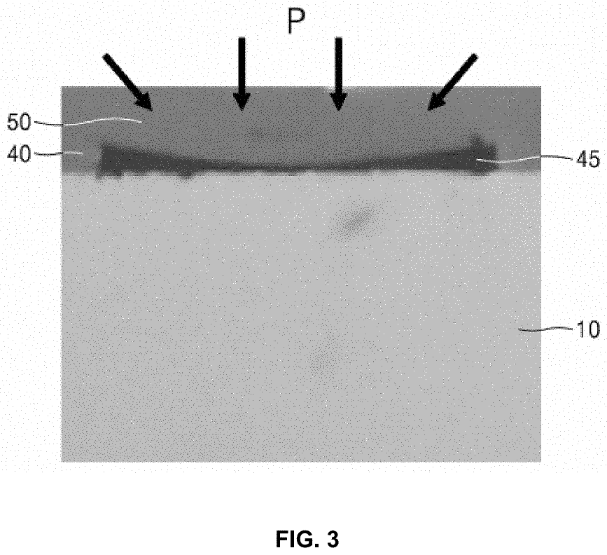

FIG. 4 is a view showing a cross-sectional structure of a SAW wafer-level package according to one embodiment of the present invention.

FIG. 5 shows an example of a state in which a first reinforcement layer is formed.

FIG. 6 shows another example of a state in which a first reinforcement layer is formed.

FIG. 7 shows an example of a state in which a second reinforcement layer is formed.

FIG. 8 shows an example of a state in which burns are formed on a second reinforcement layer.

FIG. 9 shows results of testing a degree of collapse according to the area of a cavity when pressure is applied to a conventional surface acoustic wave wafer-level package and a surface acoustic wave wafer-level package in accordance with an embodiment of the present invention.

FIG. 10 shows a cross-section of a SAW wafer-level package actually fabricated and having transfer molding applied thereto according to an embodiment of the present invention.

FIG. 11 is an enlarged view of cavity portions of FIG. 10.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

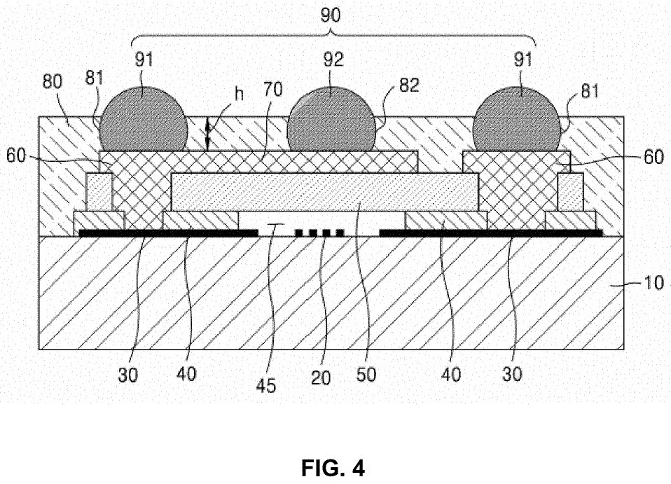

FIG. 4 shows a cross-sectional structure of a surface acoustic wave (SAW) wafer-level package according to an embodiment of the present invention.

The SAW wafer-level package according to the present embodiment includes a substrate 10, an interdigital transducer (IDT) electrode 20, a connection electrode 30, a side wall 40, a cover 50, a connection terminal 60, a first reinforcement layer 70, a second reinforcement layer 80, and bumps 90.

The substrate 10 induces a piezoelectric effect and serves to support a configuration of a device, and a piezoelectric substrate may be used. For example, a piezoelectric substrate made of LiTa2O3, LiNbO3, or the like may be used.

The IDT electrode 20 is formed on the substrate 10. A SAW device operates as a filter or the like through the mechanical vibration of the IDT electrode 20.

The connection electrode 30 serves as a medium to allow the IDT electrode 20 to be electrically connected to the outside. For example, a signal input from an external terminal is transmitted to the IDT electrode 20 through the connection electrode 30, and a signal generated by the IDT electrode 20 is transmitted to the external terminal through the connection electrode 30.

The side wall 40 is formed on the substrate 10 and outside the IDT electrode 20 to surround the IDT electrode 20. The side wall 40 may be made of, for example, a photoresist material, or the like.

The cover 50 is formed above the side wall 40 and the IDT electrode 20 to form a cavity 45, together with the side wall 40, on the IDT electrode 20. The cover 50 may be made of, for example, a photoresist material, or the like.

The connection terminal 60 is formed on the connection electrode 30 to be electrically connected to the connection electrode 30 and to protrude above the cover 50. The connection terminal 60 may be made of a material, such as Ti, Cu, Sn, Ni, Au, or the like.

The first reinforcement layer 70 is formed on the cover 50 to at least partially overlap the cavity 45 in a vertical direction. The first reinforcement layer 70 is made of a metal material, and may be made of a material, such as Ti, Cu, Sn, Ni, Au, or the like. The first reinforcement layer 70 may be connected to the connection terminal 60 as illustrated, or may be formed separately from the connection terminal 60. Also, the first reinforcement layer 70 may completely overlap the cavity 45 in a vertical direction, or may partially overlap the cavity 45 in a vertical direction. The first reinforcement layer 70 serves to protect the cover 50 from the pressure of transfer molding.

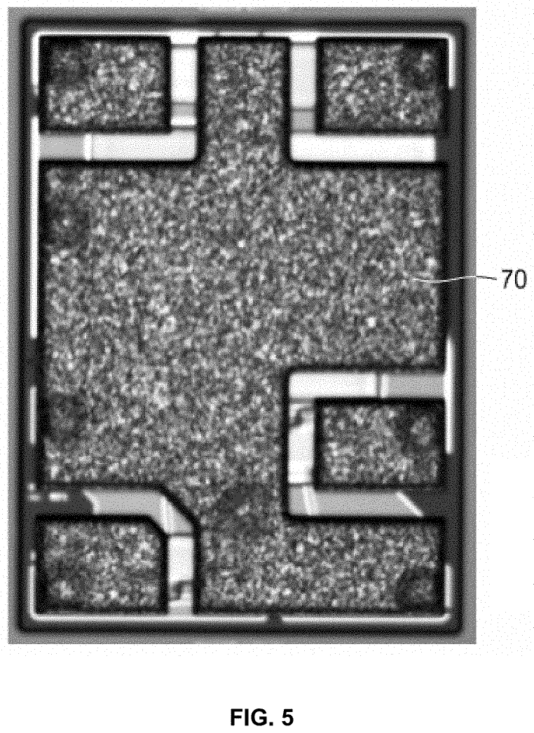

FIG. 5 shows an example of a state in which the first reinforcement layer 70 is formed. In FIG. 5, the first reinforcement layer 70 is made of a Cu material, and is formed to completely overlap the cavity in a vertical direction.

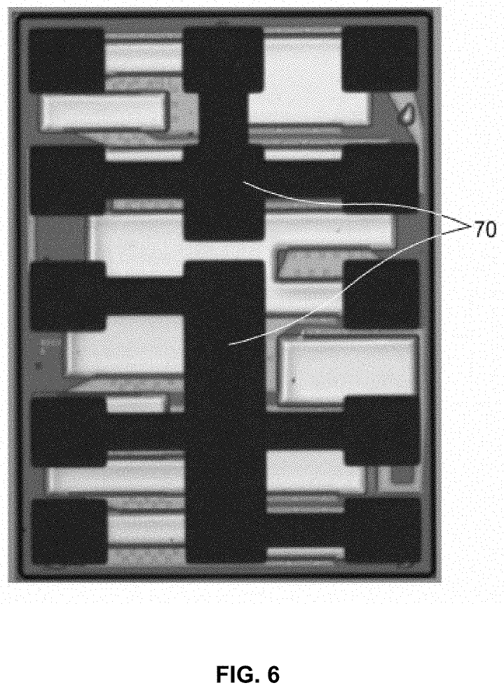

FIG. 6 shows another example of a state in which the first reinforcement layer 70 is formed. In FIG. 6, the first reinforcement layer 70 is made of a Sn material, and is formed to partially overlap the cavity in a vertical direction.

The first reinforcement layer 70 may be formed into a desired pattern through a typical patterning process and the characteristics of the device may be adjusted according to the pattern.

Referring back to FIG. 4, the second reinforcement layer 80 is formed on the substrate 10 to cover the cover 50 and the first reinforcement layer 70. The second reinforcement layer 80 may be formed of a material, such as a solid, liquid, or film-type epoxy, or a photoresist. The second reinforcement layer 80 together with the first reinforcement layer 70 further improves the function of protecting the cover 50 from the pressure of a transfer molding process. The second reinforcement layer 80 may be formed so that its height from an upper surface of the first reinforcement layer 70 is 10 μm or more. Considering the function of blocking external pressure and the thickness of the device, preferably, the second reinforcement layer 80 is formed so that its height from the upper surface of the first reinforcement layer 70 is 12 to 20 μm. For the fabrication of the bumps 90 which will be described below, the second reinforcement layer 80 has holes 81 and 82 formed in a portion corresponding to the connection terminal 60 and a portion corresponding to a part of the first reinforcement layer 70. The holes 81 and 82 may be formed through, for example, a laser processing process.

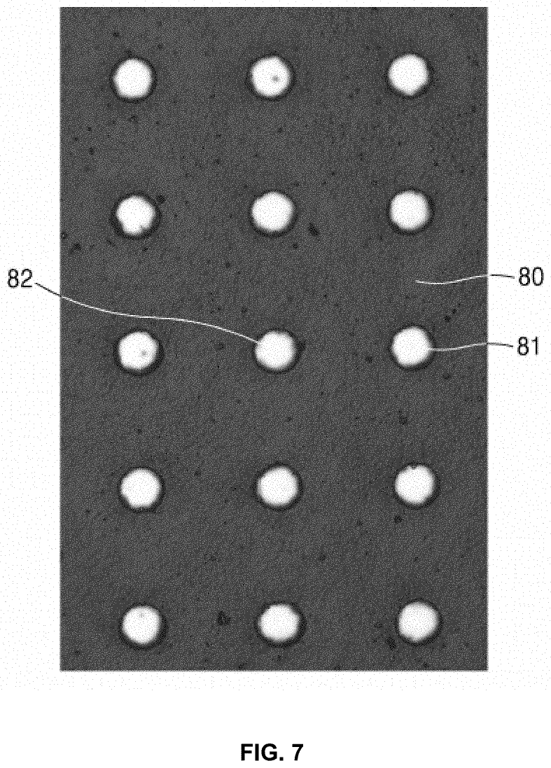

FIG. 7 shows an example of a state in which the second reinforcement layer 80 is formed. In FIG. 7, the second reinforcement layer 80 is formed of an epoxy material, and 15 holes 81 and 82 are formed therein.

Referring back to FIG. 4, the bumps 90 are formed in the holes 81 and 82 of the second reinforcement layer 80 to protrude above the second reinforcement layer 80. The bumps 90 may be formed of a solder paste, a solder ball, a copper plate, a copper pillar, or the like. The bumps 90 are two-dimensionally arranged on the second reinforcement layer 80 at predetermined intervals, and serve to distribute external pressure. Among the bumps 90, the bump 91 formed on the connection terminal 60 serves not only to disperse the external pressure, but also to electrically connect the connection terminal 60 and an external terminal (e.g., a terminal of a printed circuit board (PCB) connected to the SAW wafer-level package).

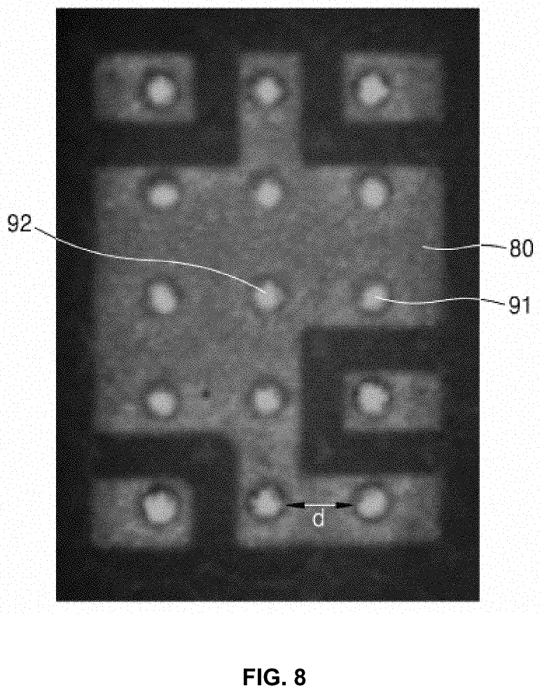

FIG. 8 shows an example of a state in which the bumps 91 and 92 are formed on the second reinforcement layer 80. In FIG. 8, 15 bumps 91 and 92 are formed. As the distance d between adjacent bumps is narrower, the ability to disperse the external pressure increases, and hence the distance d may be 200 μm or less.

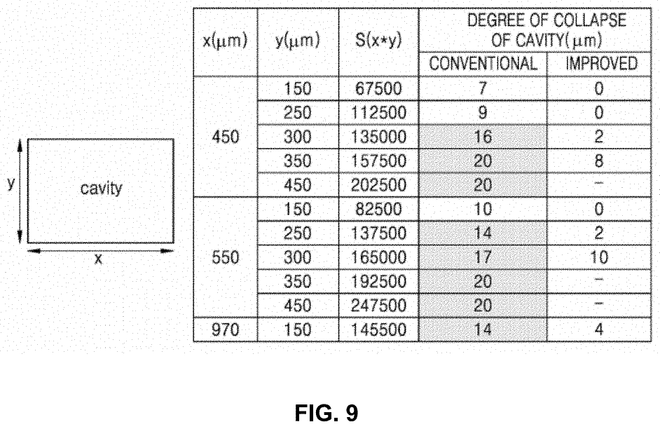

FIG. 9 shows results of testing a degree of collapse according to the area of a cavity when pressure is applied to a conventional surface acoustic wave wafer-level package and a surface acoustic wave wafer-level package in accordance with an embodiment of the present invention. An applied pressure is about 836 psi, the height of the cavity is 20 μm, x and y are the horizontal and vertical lengths of the cavity, respectively, and the “degree of collapse” is a degree to which a lower surface of the cover is lowered. Typically, when the degree of collapse exceeds 10 μm, it is determined that a defect exists.

Referring to FIG. 9, in the case of the conventional SAW wafer-level package, the degree of collapse in all cases exceeds 10 μm, except for the three cases of (x, y)=(450, 150), (450, 250), and (550, 150), it is determined that a defect exists. However, when the first reinforcement layer 70, the second reinforcement layer 80, and the bumps 90 are applied according to the embodiment of the present invention, the SAW wafer-level package passes the test as there is no collapse or the degree of collapse is 10 μm or less in all areas.

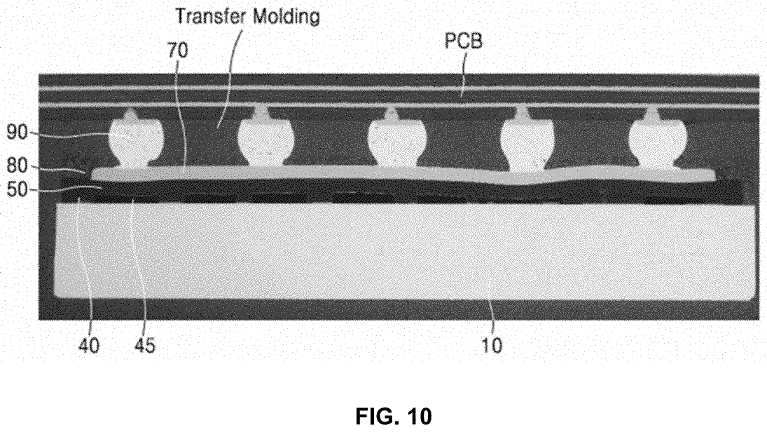

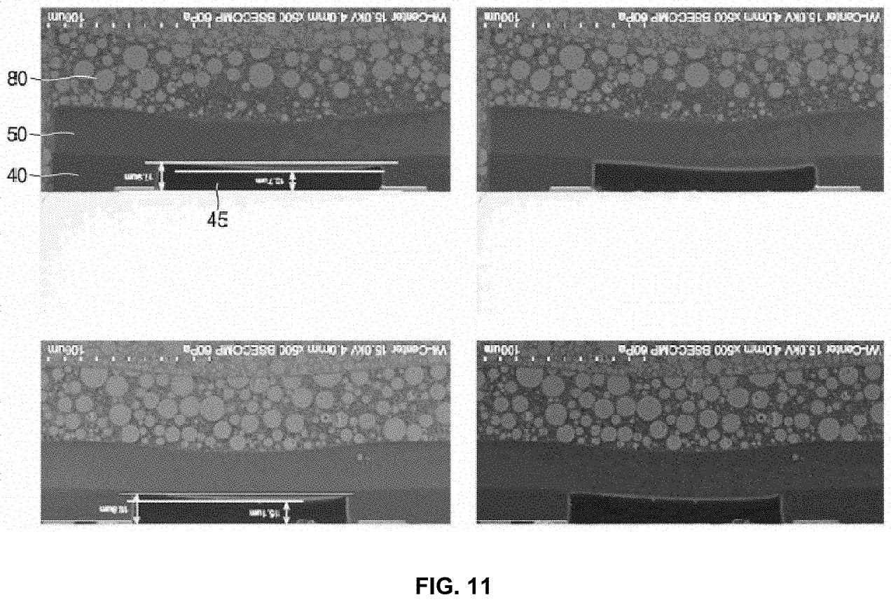

FIG. 10 shows a cross section of a SAW wafer-level package which is actually fabricated according to an embodiment of the present invention and to which transfer molding at a pressure of about 1000 psi is applied. FIG. 11 is an enlarged view of cavity portions of FIG. 10, in which it can be seen that sufficient space is secured as the degree of collapse is 10 μm or less in all the portions.

According to the present invention described above, it is possible to provide a SAW wafer-level package with improved pressure resistance that can withstand the pressure of transfer molding.

The effects of the present invention are not limited to those mentioned above, and unmentioned other effects may be clearly understood by those skilled in the art from the above descriptions.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A surface acoustic wave (SAW) wafer-level package comprising:
a substrate;
an interdigital transducer (IDT) electrode formed on the substrate;
a connection electrode formed on the substrate and electrically connected to the IDT electrode;
a side wall formed on the substrate and outside the IDT electrode;
a cover formed above the side wall and the IDT electrode to form a cavity, together with the side wall, on the IDT electrode;
a connection terminal electrically connected to the connection electrode and protruding above the cover;
a first reinforcement layer made of a metal material and formed on the cover to at least partially overlap the cavity in a vertical direction;
a second reinforcement layer formed to cover the cover and the first reinforcement layer and having holes formed in a portion corresponding to the connection terminal and a portion corresponding to the first reinforcement layer; and
bumps formed in the respective holes of the second reinforcement layer to protrude above the second reinforcement layer.

2. The SAW wafer-level package of claim 1, wherein the first reinforcement layer comprises Ti, Cu, Sn, Ni, or Au.

3. The SAW wafer-level package of claim 1, wherein the second reinforcement layer comprises an epoxy or a photoresist.

4. The SAW wafer-level package of claim 1, wherein the bumps comprise a solder paste, a solder ball, a copper plate, or a copper pillar.

5. The SAW wafer-level package of claim 1, wherein the first reinforcement layer is formed to completely overlap the cavity in the vertical direction.

6. The SAW wafer-level package of claim 1, wherein the first reinforcement layer is formed to partially overlap the cavity in the vertical direction.

7. The SAW wafer-level package of claim 1, wherein a distance between adjacent bumps among the bumps is 200 μm or less.

8. The SAW wafer-level package of claim 1, wherein the second reinforcement layer has a height of 10 μm or more from an upper surface of the first reinforcement layer.
